(19) United States
(12) Patent Application Publication
(10) Pub. No.: US 2008/0020258 A1
(43) Pub. Date: Jan. 24, 2008

(54) CURRENT COLLECTION BOARD FOR FUEL CELL

(76) Inventors: Tsang-Ming Chang, Taipei (TW); Ko-Chen Shen, Taipei (TW); Wen-Sen Hsieh, Taipei (TW)

Correspondence Address: G. LINK CO., LTD, 3550 BELL ROAD, MINOOKA, IL, 60447, US

(21) Appl. No.: 11/459,388

(22) Filed: Jul. 24, 2006

(51) Int. Cl. H01M 8/02; H05K 7/00

(52) U.S. Cl. 429/34; 361/748

(57) ABSTRACT

The present invention discloses current collection board for a fuel cell. The current collection board for a fuel cell comprises a substrate and at least one current collection bar. The substrate includes at least one hollow portion. The current collection bars are made of stainless steel. Further, the current collection bars respectively cover the hollow portions of the substrate, and are fixed to the substrate.

### FIELD OF THE INVENTION

The present invention relates to a current collection board for a fuel cell, and more particularly, to a current collection board combining a printed circuit substrate and stainless steel, which is easily fabricated at low cost.

### BACKGROUND OF THE INVENTION

A conventional fuel cell includes components such as an anode current collection board, a cathode current collection board and at least one membrane electrode assembly (MEA), wherein these components are assembled compactly to form the cell. Consequently, the anode current collection board and the cathode current collection board applied to certain types of fuel cells are not suitable for other types of cells. It is also difficult with respect to the traditional structures of the anode current collection board and the cathode current collection board to fit them for manifold MEAs, especially for newly-developed MEAs. As a result, such newly-developed MEAs' quality is not tested and verified unless another special anode current collection board and cathode current collection board are fabricated.

In prior arts, graphite plates have been applied to conventional current collection boards. Though graphite plates are able to collect current, they are physically fragile. It is thus not economic to make current collection boards from graphite plates. Furthermore, graphite plates occupy a large amount of space, so the current collection boards made thereby are not minimized accordingly.

Therefore, an improved current collection board that is easily fabricated at low cost is needed to overcome the aforesaid disadvantages.

### SUMMARY OF THE INVENTION

It is a primary object of the invention to provide a current collection board for a fuel cell, which combines the features of a printed circuit substrate and stainless steel. Hence, the current collection board is easily fabricated at low cost.

Another object of the present invention is to provide a current collection board for a fuel cell, which can fabricate the corresponding collection board by following the shape and the size of the membrane electrode assembly (MEA) for easy fabrication at low cost.

In accordance with the aforesaid objects of the invention, a current collection board for a fuel cell is provided, which comprises a substrate and at least one current collection bar. The substrate includes at least one hollow portion. The current collection bars are made of stainless steel. Further, the current collection bars respectively cover the hollow portions of the substrate, and are fixed to the substrate.

### BRIEF DESCRIPTION OF THE DRAWINGS

The foregoing aspects, as well as many of the attendant advantages and features of this invention, will become more apparent by reference to the following detailed description, when taken in conjunction with the accompanying drawings, wherein:

FIG. 1 is an elevation exploded diagram showing a current collection board for a fuel cell according to an embodiment of the invention;

FIG. 2 is an elevation exploded diagram of FIG. 1 in the present invention;

FIG. 3 shows the structure of a current collection bar according to an embodiment of the invention;

FIG. 4 shows the structure of a current collection bar according to another embodiment of the invention;

FIG. 5 shows the structure of a current collection bar with thru holes according to an embodiment of the invention; and

FIG. 6 is a diagram showing a current collection board in the fabrication state.

### DETAILED DESCRIPTION OF THE INVENTION

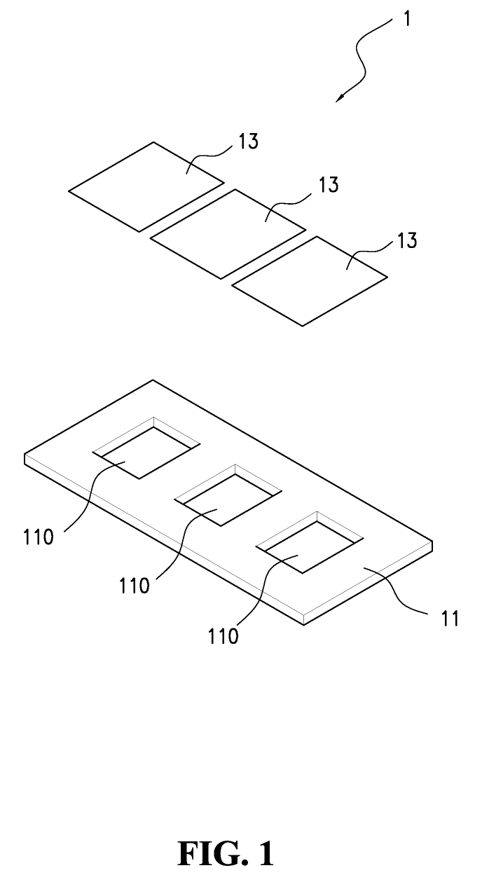

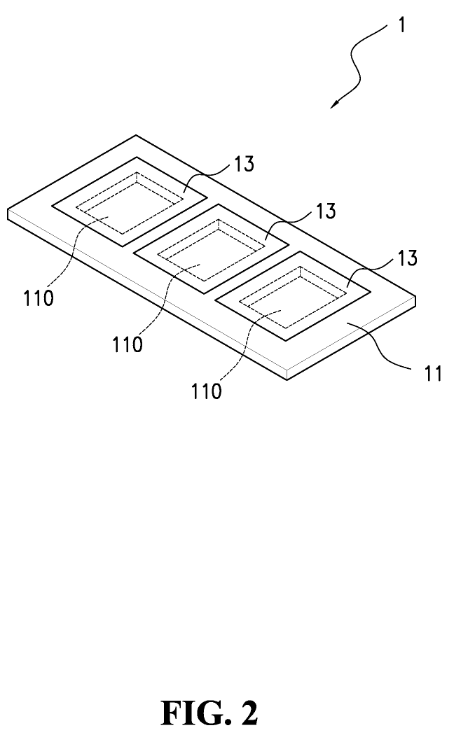

FIG. 1 is an elevation exploded diagram showing a current collection board for a fuel cell according to an embodiment of the invention. FIG. 2 illustrates the elevation diagram of FIG. 1 in the present invention. The current collection board 1 of the present invention mainly comprises a substrate 11 and at least one current collection bar 13. The substrate may be made of a printed circuit substrate, such as an FR4 substrate, an FR5 substrate, an epoxy resin substrate, a glass fiber substrate, a ceramic substrate, a polymeric plastic substrate, or a composite substrate. One or more hollow portions 110 are disposed over the substrate 11 corresponding to the positions of the membrane electrode assemblies (MEAs) (not shown).

The current collection bar 13 is made of stainless steel. The shape and the size of each current collection bar 13 should be considered for correspondence to the shape and the size of the membrane electrode assemblies (MEAs) (not shown). For example, when the shape of the membrane electrode assemblies (MEAs) is rectangular, the current collection bar 13 should also be rectangular. However, the above rectangular structure for the current collection bar 13 is only one preferred embodiment of the present invention. The current collection bar of the present invention is not only limited to a rectangular shape.

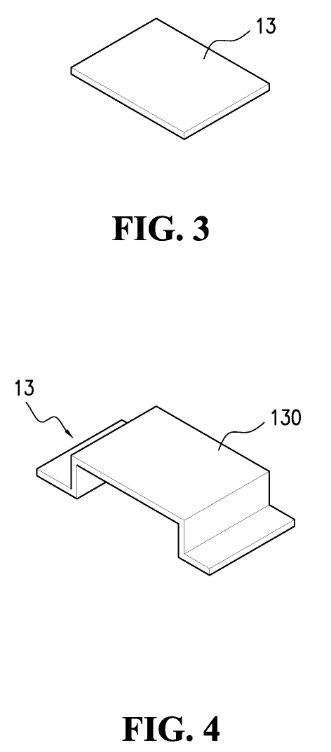

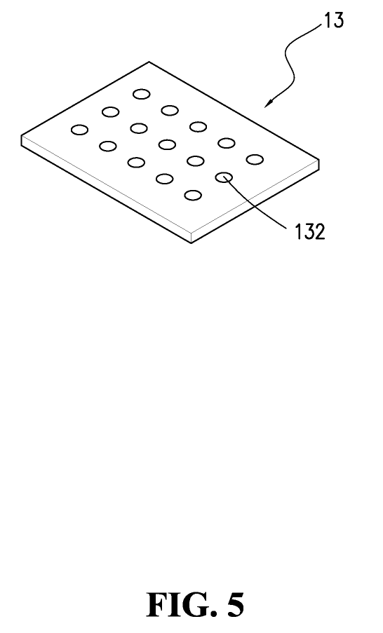

FIG. 3 shows the structure of a current collection bar according to an embodiment of the invention. FIG. 4 shows the structure of a current collection bar according to another embodiment of the invention. FIG. 5 shows the structure of a current collection bar with thru holes according to an embodiment of the invention. The structure of the current collection bar 13 can be flat. Instead, the structure of the current collection bar 13 can be flat with a protruding portion 130. The current collection bar 13 as shown in FIG. 3 is used to cover the corresponding hollow portion 110. The protruding portion of the current collection bar 13 as shown in FIG. 4 is deployed to the corresponding hollow portion 110. As shown in FIG. 5, the current collection bar 13 further includes at least one thru hole 132. As such, fuels pass through the thru holes 132 and flow into the MEAs, respectively (not shown). Also, the products produced during electrochemical reactions in the MEAs pass through the thru holes 132 and drain away.

For accommodating a current collection bar 13 to various conditions of fuels, the surface of the current collection bar 13 in the present invention is further treated by a protection process and/or an anticorrosive/acid-proof process. The surface of the current collection bar 13 is plated with a thin metal layer of copper (Cu) or gold (Ag). Consequently, the current collection bar 13 is not damaged by corrosion from fuels, and the performance of the current collection bar 13 is enhanced.

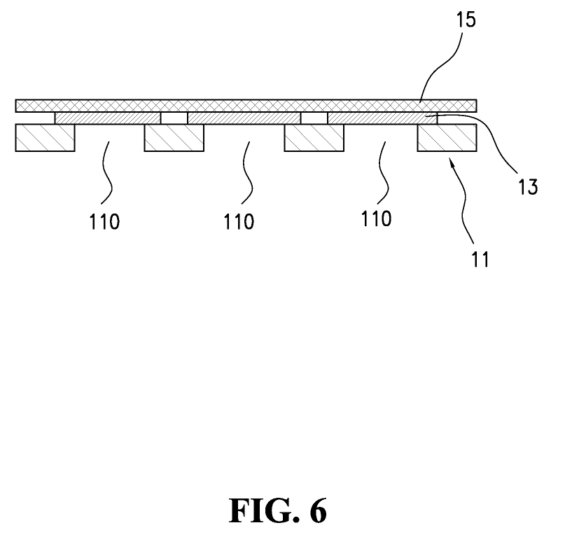

FIG. 6 is a diagram showing a current collection board in the fabrication state. In order to fabricate the current collection board 1 of the present invention, the substrate 11, the current collection bar 13, and the adhesion layer 15 are disposed from top to bottom, respectively. The current collection board 1 is fabricated further by sealing with a heat seal machine. The above adhesion layer 15 is made of glass fiber resin.

The current collection board 1 above may be applied to manifold fuel cells, such as a fuel cell with methanol fuels, a fuel cell with liquid fuels, a fuel cell with gaseous fuels, or a fuel cell with solid fuels.

The aforementioned current collection board combines the benefits of a printed circuit substrate and stainless steel with the physical properties of these two kinds of metals, so it has the following advantages and improvements:
1. The substrate of the current collection board is fabricated from a printed circuit substrate, which is less expensive and processed easily. Furthermore, the current collection bar having stainless steel is easily fabricated at low cost. So the current collection board made thereby is favorable for mass production; and
2. In addition to possessing the ability to collect current, the surface of the current collection bar is further treated by a protection process and/or an anticorrosive/acid-proof process. Therefore, the current collection bar has a longer lifetime and an improved ability to collect current.

While the invention has been particularly shown and described with reference to the preferred embodiments thereof, these are, of course, merely examples to help clarify the invention and are not intended to limit the invention. It will be understood by those skilled in the art that various changes, modifications, and alterations in form and details may be made therein without departing from the spirit and scope of the invention, as set forth in the following claims.

What is claimed is:

1. A current collection board for a fuel cell, comprising:
a substrate including at least one hollow portion; and
at least one current collection bar made of stainless steel and respectively covering at least one hollow portion of said substrate, wherein said current collection bars are fixed to said substrate.

2. The current collection board of claim 1, wherein the substrate of said substrate comprises a printed circuit substrate.

3. The current collection board of claim 2, wherein the substrate of said substrate is one selected from an FR4 substrate, an FR5 substrate, an epoxy resin substrate, a glass fiber substrate, a ceramic substrate, a polymeric plastic substrate, or a composite substrate.

4. The current collection board of claim 1, wherein the surface of said current collection bar is plated with a thin metal layer of copper (Cu).

5. The current collection board of claim 1, wherein the surface of said current collection bar is plated with a thin metal layer of gold (Ag).

6. The current collection board of claim 1, wherein the surface of said current collection bar is treated by a protection process and/or an anticorrosive/acid-proof process.

7. The current collection board of claim 1, wherein said current collection bar is flat.

8. The current collection board of claim 1, wherein said current collection bar has a protruding portion, and the protruding portion of said current collection bar is deployed to the corresponding hollow portion.

9. The current collection board of claim 1, wherein said current collection bar further includes at least one thru hole, and the thru holes are penetrated through said current collection bar.
